(19) United States
(12) Patent Application Publication
(10) Pub. No.: US 2025/0273517 A1
(43) Pub. Date: Aug. 28, 2025

(54) APPARATUS AND METHODS FOR SURFACE INSPECTION

(71) Applicant: Adeia Semiconductor Bonding Technologies Inc., San Jose, CA (US)

(72) Inventors: Bongsub Lee, Santa Clara, CA (US); Oliver Zhao, Sunnyvale, CA (US); Laura Wills Mirkarimi, Sunol, CA (US)

(21) Appl. No.: 18/771,340

(22) Filed: Jul. 12, 2024

Related U.S. Application Data
(60) Provisional application No. 63/556,802, filed on Feb. 22, 2024.
(60) Provisional application No. 63/644,767, filed on May 9, 2024.
(60) Provisional application No. 63/651,882, filed on May 24, 2024.

(51) Int. Cl. H01L 21/66; H01L 23/00

(52) U.S. Cl. CPC H01L 22/12; H01L 24/05; H01L 24/08; H01L 24/06; H01L 2224/05567; H01L 2224/05647; H01L 2224/06131; H01L 2224/08145

(57) ABSTRACT

A method for surface defect inspection can comprise obtaining topographical data from one or more portions of a semiconductor element. The semiconductor element can have a surface comprising a dielectric and a plurality of metal pads. The method can further comprise processing the topographical data of the one or more portions of the semiconductor element to determine at least a first property of the plurality of metal pads, computing at least one variability value for the first property, and identifying candidate defects in the one or more portions of the semiconductor element based at least in part on the at least one variability value.

### CROSS-REFERENCE TO RELATED APPLICATIONS

This application claims priority to U.S. Provisional Application Nos. 63/651,882, filed May 24, 2024, titled “APPARATUS AND METHODS FOR SURFACE INSPECTION,” 63/644,767, filed May 9, 2024, titled “APPARATUS AND METHODS FOR SURFACE INSPECTION AND PROCESSING FOR VIABILITY OF HYBRID BONDING,” and 63/556,802, filed Feb. 22, 2024, titled “APPARATUS AND METHODS FOR SURFACE INSPECTION AND PROCESSING FOR VIABILITY OF HYBRID BONDING,” the disclosures of each of which are incorporated herein by reference in their entirety for all purposes.

### BACKGROUND

### Field

The field relates to inspecting semiconductor elements, including the inspection of dies or wafers prepared for hybrid bonding.

### Description of Related Art

2.5D and 3D packaging, including die stacking, facilitate the packaging of an increasing number of active devices into a relatively small footprint. Hybrid bonding is one fabrication process that enables such die stacking, which in turn can advance device performance and optimize space utility. Hybrid bonding entails preparing the surfaces to be bonded, including planarizing the surfaces such that the surfaces are extremely flat. Because the quality of the hybrid bonding depends on the quality of the prepared surfaces, inspection apparatuses and/or processes can be used to ensure the surfaces are free of defects prior to bonding.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A is schematic representation of a portion of a wafer surface.

FIG. 1B is a schematic representation of a semiconductor element.

FIG. 2A is a schematic illustration of acquiring topography data of a wafer surface, according to one embodiment.

FIG. 2B is a schematic of a processing system, according to one embodiment.

FIG. 2C is a schematic of a topographical line profile obtained from topography data of a wafer surface, according to one embodiment.

FIG. 2D is a plot illustrating a histogram of heights determined from topography data of a wafer surface, according to one embodiment.

FIG. 2E is a schematic representation of a wafer surface having identified metal pads, according to one embodiment.

FIG. 3A is a view of a portion of a phase shift interferometry (PSI) image of a wafer surface with three metal pads lacking surface defects, according to one embodiment.

FIG. 3B is a view of a portion of a PSI image of a wafer surface with three metal pads, including one damaged metal pad, according to one embodiment.

FIG. 4A is a plot of standard deviation values as a function of PSI image number, according to one embodiment.

FIG. 4B are views of PSI images of different wafer surfaces including defects, according to one embodiment.

FIG. 5 is a schematic block diagram illustrating a method for inspecting a surface of a semiconductor element, according to one embodiment.

FIG. 6 is a view of a graphical map illustrating metal pad recess variation on a wafer-scale, according to one embodiment.

FIG. 7 is a plot illustrating the relationship between apparent metal pad recess values and expected metal pad recess values, according to one embodiment.

FIGS. 8A-8B are schematic cross sections illustrating direct bonding of microelectronic elements, according to one embodiment.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and include other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

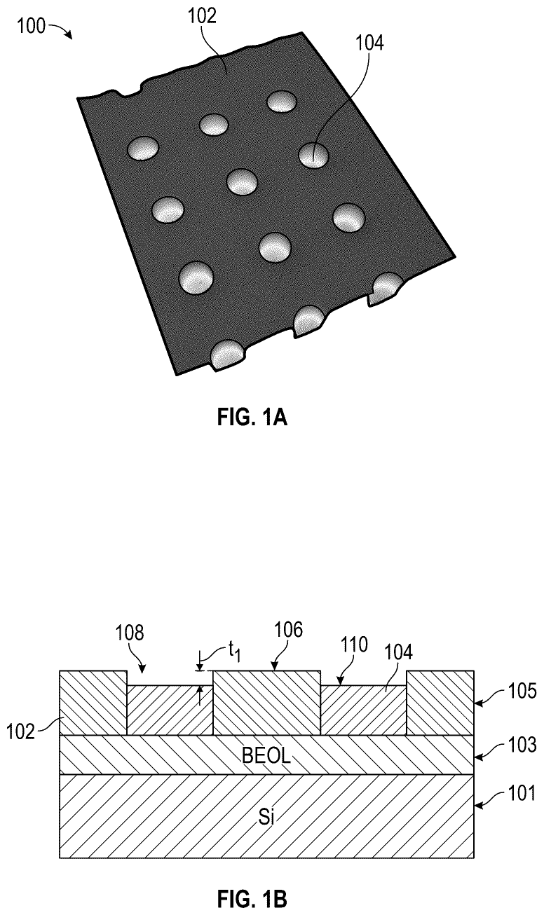

The surfaces of wafers or dies prepared for hybrid bonding (described herein) are polished surfaces that can comprise a plurality of metal pads in a dielectric layer. FIG. 1A illustrates a 3D representation of a surface 100 for hybrid bonding, showing a dielectric 102 and a plurality of metal pads 104. The wafer or die can include multiple layers. For example, as shown in FIG. 1B, the wafer or die can have a first layer comprising a semiconductor layer 101 or semiconductor substrate (e.g., Si) and one or multiple metallization layers 103 (e.g., back-end-of-line (BEOL) layer(s)) disposed over the semiconductor layer 101. The metallization layer(s) 103 can comprise various routing or redistribution layers, with a bonding layer 105 at the outer surface (e.g., the bonding layer 105 can include a nonconductive or dielectric layer 102 including metal pads 104 embedded therein). As part of the surface preparation, the metal pads 104 are slightly recessed relative to the surface 106 of the dielectric layer 102. The recess 108 (e.g., the depth of the metal pad 104 below the dielectric surface 106) can have a value ti on the order of nanometers (e.g., less than 10 nm, less than 5 nm, etc.). The surfaces 106, 110 can be plasma-activated and brought into contact with a surface of a second wafer, at which point room-temperature bonding can occur between the dielectric surfaces 106, and a gap forms between the metal pads 104 to be bonded. In a subsequent step of annealing, the dielectric bonding becomes stronger, and thermal expansion closes the gap between opposing pads. In this bonding process, metal compression occurs without external pressure. The success of hybrid bonding these surfaces depends on the quality of the surfaces prepared for bonding. In particular, control of the surface quality on a nanoscale level can be important for providing adequate device yield.

Atomic force microscopy (AFM) is one approach that can characterize the wafer surfaces on a nanometer level. Because AFM has a depth resolution of less than 0.1 nm, it is capable of inspecting hybrid bonding surfaces to the nanoscale level. However, AFM has a limited imaging field of view (FOV) size (e.g., <100 μm) and a low data acquisition rate (e.g., acquisition time per image is on the order of minutes). Considering that fabricated wafers can be hundreds of millimeters in size and include millions of metal pads, an AFM inspection approach would require extraordinary amounts of time for imaging and inspecting an entire wafer for surface quality, including the quality of the metal pads, to determine whether any defects exist that could impact hybrid bonding. Conventional optical microscopy techniques can be another approach to characterizing wafer surfaces. However, most optical microscopes do not provide height information, or the height resolution can be insufficient to detect small defects (e.g., depth from defocus techniques). An optical profilometry technique called chromatic white light profilometry has a height resolution of about 10 nm, which may or may not be sufficient depending on the nature of defects. Thus, a high resolution, fast-throughput inspection technique is desired.

Optical techniques, such as various optical interferometry techniques can be used for inspecting wafer surfaces prepared for hybrid bonding. Combining such techniques with a statistical analysis process can yield fast and robust surface detection of defects.

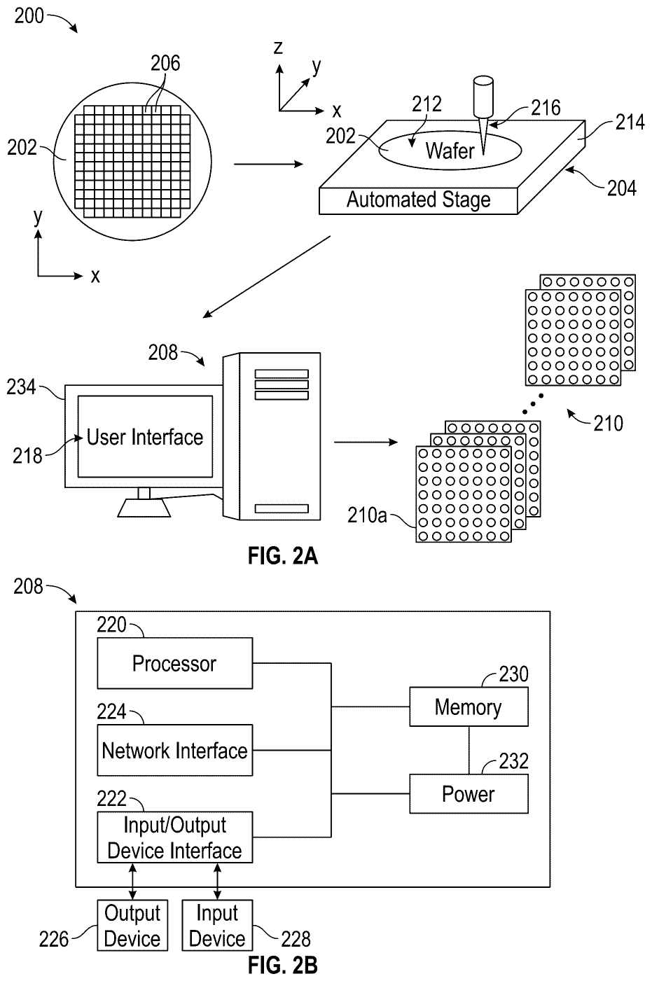

Various embodiments disclosed herein relate to a system and a method for surface defect inspection (or a defect inspection technique) using statistical analysis of topography data. FIG. 2A is a schematic illustration of a surface defect inspection system 200 acquiring topography data, including z-depth information of a semiconductor element 202 (e.g., a die, a singulated or diced die, a wafer, a reconstituted wafer, etc.). An imaging apparatus 204 (e.g., an imaging system or an optical profilometry apparatus) capable of obtaining topography data, such as an image or imaging data, can be used to obtain or acquire topographical data from one or more portions of the semiconductor element 202 (e.g., portion of a wafer or a die 206). A processing system 208 comprising processing electronics (not shown) can receive the topographical data from the imaging apparatus 204, process the data to identify regions of interest, and can output it in a desired format. For example, the processing system 208 can output a plurality of images 210 (e.g., topographical images of a semiconductor surface) illustrating topographical data of a surface 212. The semiconductor element 202 can have a surface 212 comprising a first material (e.g., a dielectric such as SiO₂) and a second material (e.g., metal pads such as Cu pads). The surface defect inspection system 200 can further include a user interface 218 for subsequent analysis of the topographical data and for user interaction with the processing system 208.

In some embodiments, the processing system 208 can also be used to facilitate data acquisition by the imaging apparatus 204. In some embodiments, the data acquisition is automated. For example, the processing system 208 can comprise programmable instructions in a computer readable medium stored on any suitable computer readable medium (e.g., a suitable memory device such as RAM, ROM, etc.) configured to instruct the imaging apparatus 204 to move a sample stage 214 relative to the imaging pathway 216 to acquire topographical data from new fields of view of the semiconductor element 202 (e.g., portions of a wafer or die 206). In some embodiments, the sample stage 214 is an automated sample stage. Utilizing an automated stage for imaging new portions of the semiconductor element's surface 212 can help decrease the time it takes to image the surface of one semiconductor element in its entirety.

FIG. 2B illustrates a schematic block diagram depicting an illustrative general architecture of a processing system 208 (or control unit) for implementing aspects of a surface defect inspection system 200. The processing system 208 can include more (or fewer) components than those shown in FIG. 2B. The processing system 208 can include a processor 220 and an input/output (I/O) device interface 222. In some embodiments, the I/O device interface 222 can include the user interface 218 for operating or controlling the imaging apparatus 204 and/or data analysis. In some embodiments, the processing system 208 can include a network interface 224. In some embodiments, network interface 224 can allow for short-range wireless connections (e.g., Bluetooth® connection). The processing system 208 components can communicate with one another by way of a communication bus. As illustrated, the processing system 208 is associated with, or in communication with, at least one output device 226 and at least one input device 228. For example, the output device 226 can be the sample stage 214. The network interface 224 can provide the processing system 208 with connectivity to one or more networks or computing systems. The processor 220 can thus receive information and instructions from other processing systems or services via a network (e.g., wireless personal area network (WPAN), local area network (LAN), etc.). The processor 220 can also communicate to and from the memory 230 and further provide output information (e.g., a plurality of images 210) for an output device 226 (e.g., a display 234) via the I/O device interface 222. The I/O device interface 222 can accept input from the input device 228 (e.g., imaging data or information from the imaging apparatus 204). The memory 230 can contain computer program instructions that can be executed by the processor 220. In some embodiments, the memory 230 can include RAM, ROM, and/or other persistent or non-transitory computer-readable storage media. The processing system 208 further includes a power source for providing power 232 to the processing system 208.

In some embodiments, additional elements can be included in the surface defect inspection system 200 to facilitate the acquisition of topographical data. For example, an automated sample system could be included and coupled to the optical profilometry apparatus. Such an automated sample system could be configured to place unimaged semiconductor element samples onto the automated sample stage for imaging and remove imaged semiconductor element samples from the automated sample stage, facilitating, in part, an automated and relatively quick, high throughput surface defect inspection process.

In some embodiments, the imaging apparatus 204 can have the capability to operate in various imaging modes (e.g., phase shift interferometry, white light interferometry, etc.). In some embodiments, the imaging apparatus 204 can be a phase shift interferometer. In some embodiments, a recess to be measured on the surface of a semiconductor element can have a value greater than approximately 10 nm; a value less than approximately 10 nm; or a value between approximately 10 nm and approximately 50 nm. In some embodiments, instead of a recess, a protrusion can exist (e.g., particles or other foreign matter), in which case the protrusion can have a value in the range of approximately-10 nm; or less than approximately-10 nm (e.g., approximately-20 nm). Thus, having nanometer or sub-nanometer vertical resolution facilitates detecting fine nanoscale detail on the surface of a semiconductor element.

In some embodiments, the imaging apparatus has a vertical (z-depth) resolution on the order of nanometers. In some embodiments, the imaging apparatus can have a vertical resolution that is in a nanometer range. Still, in some embodiments, the imaging apparatus can have a vertical resolution in the angstrom range. Further, in some embodiments, the imaging apparatus can have a lateral resolution approximately in the half-micron range. Such a lateral resolution allows for the measuring of metal pad sizes on semiconductor element surfaces. Still in some embodiments, the imaging apparatus can have a lateral resolution less than approximately a half-micron. In some embodiments, the imaging apparatus can have an imaging size (e.g., field of view) that is between approximately 300 μm and approximately 4 mm. In some embodiments, the acquisition time of the imaging apparatus is on the order of seconds.

Once the topographical data has been collected from a semiconductor element 202 (e.g., wafer or die), the data can be further processed and analyzed for detecting desired features to enable image segmentation or object localization. In some embodiments, regions (e.g., regions of interest) can be determined from a semiconductor element 202 having a first material (e.g., dielectric 102) and a second material (e.g., metal pads 104 or pads comprising conductive material). FIG. 2C schematically illustrates a line profile that can be obtained from the topographical data. The line profile shows the depth data as a function of a lateral position on the semiconductor element 202. For example, the line profile can illustrate the data taken along a z-axis as a function of the x-position on the semiconductor element 202. The line profile can be of a portion of a wafer or a die 206 having a dielectric surface 106 and metal pads 104 recessed (or protruding) relative to the dielectric surface 106, where the recess 108 can be determined by subtracting the z-depth value of the surface of the metal pads 104 from the z-depth value of the dielectric surface 106. The topographical data can additionally be used to generate a distribution of the surface data acquired. For example, the topographical data can be used to extract a histogram of the heights for all surface points, as shown in FIG. 2D. FIG. 2D shows that in some embodiments the height histogram can comprise a bimodal distribution, having peaks corresponding to the metal pads 104 and the dielectric 102. Having a distinct separation between what portions of the surface correspond to the metal pads 104 or the dielectric 102 enables image detection and/or segmentation, which in turn facilitates characterizing the surface 212 and/or focusing the analysis on specific elements (e.g., focus analysis on just the metal pads 104, or focus analysis on just the dielectric 102). In some embodiments, phase shift interferometry (PSI) (see, for example, de Groot, P., Phase Shifting Interferometry, 2011, In: Leach, R. (eds) Optical Measurement of Surface Topography, Springer, Berlin, Heidelberg, https://doi.org/10.1007/978-3-642-12012-1_9) can be used to acquire the image data. PSI is an optical technique using a light source having a short coherence length (e.g., monochromatic, or nearly monochromatic light source) that can characterize surfaces. With PSI, interference patterns are acquired (e.g., interferograms) through controlled phase shifts. The PSI data is analyzed, and the surface being measured is reconstructed. Because PSI is sample dependent, it can result in apparent recess value measurements that are deeper than they physically (actually) are, which can yield PSI images having greater contrast between the dielectric background and the metal pads. Thus, in some embodiments using PSI can allow for relatively easy automatic detection of metal pads against a dielectric background.

In one embodiment, the analysis is tailored toward inspecting the quality of the metal pads 104, and thus once the metal pads 104 can be distinguished from the dielectric 102 in the topographical data, the metal pads 104 can be detected and labeled, as in FIG. 2E (showing a portion of a PSI image (e.g., a first image 210a) having metal pads 104 that can be labeled or numbered “i−1,” “i,” “i+1,” . . . where “i” is an integer value greater than 0). Identifying and labeling the metal pads allow for subsequent characterization of specific metal pads. For example, a metal pad having a unique identifier or label can be isolated by a software program, and information in the image data (e.g., pixels) corresponding to the labeled metal pad can be analyzed to characterize the labeled metal pad. Although metal pads are specified in this method, the method is not limited to only analyzing and characterizing metal pads. For example, the method can be implemented for analyzing a portion (or arbitrary region) of a wafer surface and identifying one or more regions having high variations. In some embodiments, a portion of the wafer surface can comprise a dielectric material and no pads. In some embodiments, a portion of the wafer surface can comprise 1 metal pad. In some embodiments, a portion of the wafer surface can comprise 1 metal pad and the dielectric region the pad might be centered on. In some embodiments, a portion of the wafer surface can comprise 5 metal pads and a dielectric. In some embodiments, a portion of the wafer surface can comprise greater than 5 metal pads (e.g., 100 pads) and the dielectric. In some embodiments, a portion of the wafer to be inspected and analyzed can be chosen arbitrarily based on a geometric grid defined across the wafer.

Once the topographical data corresponding to the metal pads 104 in the semiconductor element 202 has been processed such that the metal pads 104 in a specified region (e.g., region of interest) have been detected and labeled (or identified in some way), the metal pads 104 can be characterized. For example, feature parameter values for the regions of interest in the topographical data (e.g., topographical images) can be determined. In one embodiment, at least one parameter value corresponding to a first property of the metal pads 104 can be determined. For example, recess (or protrusion), Rv, and Rt values can be determined. Recess values (e.g., recess depth values) correspond to the depth of the metal pads 104 relative to the dielectric surface 102. Rv values correspond to the maximum depth of the recess 108 (e.g., level of the deepest point in a metal pad), which help determine whether deep defects exist, such as pinholes. Rt values correspond to a peak-to-valley difference within a pad area, which help locate tall or deep defects. These values can be plotted and/or statistical values (e.g., statistical parameter values such as standard deviations) can be determined, and the statistical values can then be further examined or evaluated or analyzed (e.g., plotted).

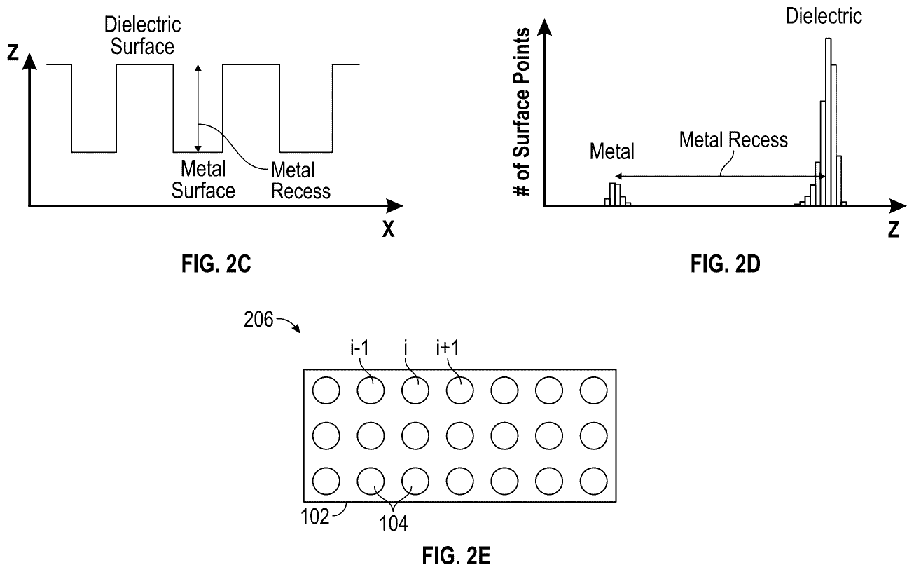

Abnormal values (e.g., candidate defects) can subsequently be identified from the feature parameter values and/or the statistical values determined from the feature parameter values. Image numbers associated with abnormal values can be used to review or examine corresponding images to determine whether a defect exists. For example, FIG. 3A shows a portion of a PSI image 210a including a portion of a wafer or a die 206 having three metal pads 302a-c (e.g., Cu pads). The metal pads 302a-c are approximately flat and lack surface defects. Consequently, the metal pads 302a-c have similar Rv values. That is, the Rv value of the first, second, and third pads 302a-c are approximately the same. Thus, taking a standard deviation of these Rv values would yield a result that is close to or approximately zero. In contrast, FIG. 3B shows a portion of a PSI image 210a including a portion of a wafer or a die 206 having three metal pads 302a-c (e.g., Cu pads), where one pad 302c is damaged or otherwise irregular. In this instance, the first and second pads 302a-b have similar Rv values, but the third pad 302c has an absolute Rv value considerably greater than that of the first and second pads 302a-b. Consequently, the standard deviation of these Rv values would yield a result significantly greater than zero. The large standard deviation can thus serve as an indicator of defects. In some embodiments, the statistical value can comprise a measure of variability (e.g., a standard deviation, etc.) within the dataset of recess values. In some embodiments, the statistical value can comprise a measure of central tendency (e.g., a mean value, etc.). Determining such statistical values and comparing them is beneficial in that what is being searched for is how they compare with one another to find values that are out of the ordinary and thus likely defective. Thus, such a method can proceed relatively quickly, as carrying out calibration (or similar) steps may be unnecessary.

In other embodiments, the parameters (e.g., recess values, Rv, and/or Rt) can be individually collected and analyzed by the processing system 208, and, if a particular parameter (e.g., recess value, Rv, or Rt) exceeds a threshold (e.g., 25 nm, 50 nm, 100 nm, etc.), the processing system 208 can store an indication that the particular pad has abnormally high variability. The processing system 208 can communicate with the user interface 218 to alert the user of the portions of the wafer (e.g., pads or regions of pads) that may be defective. Thus, in various embodiments, variability of the parameter (e.g., recess or deep defects such as pinholes) within the data set can be computed using statistical calculations representative of the data set as a whole (such as standard deviation) or by comparing individual parameter values with a threshold and presenting abnormal values or defective locations to the user.

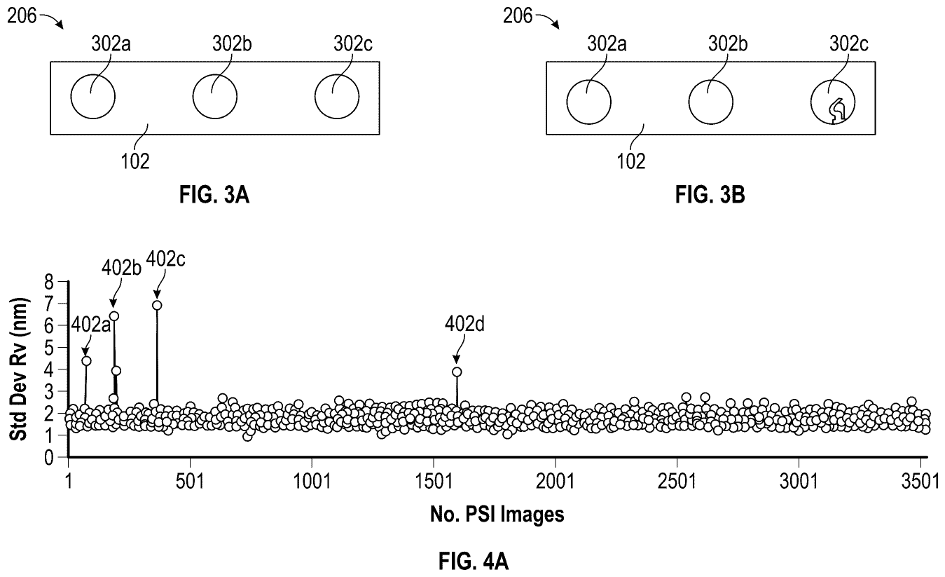

Thousands of optical profilometry images 210 can be acquired or captured from a semiconductor element 202. The statistics of the characteristics of the semiconductor element 202 can then be analyzed to assess the quality of the surface 212 of the semiconductor element 202. For example, FIG. 4A shows a graph illustrating the standard deviation of Rv values from PSI data. In this graph, approximately 3500 PSI images 210 were collected and the standard deviations of the Rv values were plotted. At least 4 data points (e.g., possible defect values 402a-d or candidate defect indicators) are significantly greater than the majority of the plotted standard deviation values. These possible defect values 402a-d (or candidate defect indicators) can be traced to their corresponding PSI image 210 and then examined more closely. The images corresponding to the 4 possible defect values 402a-d having abnormally large standard deviation values are shown in FIG. 4B. In 402a, c, and d, the PSI images 210 are of a portion of a wafer or a die 206 having a plurality of metal pads 104. An expanded view of a portion of the corresponding PSI image 210 shows the presence of one or more defective metal pads. In 402b, the PSI image 210 is a portion of a wafer or a die 206 that is missing metal pads and further includes irregular pads. This analytical method provides a fast approach to identify possible surface defects (e.g., pinhole, scratch, oxidation, corrosion, particles, etc.) from thousands of images collectively comprising hundreds of thousands of metal pads (or at least millions of metal pads in some embodiments). The surface defect inspection system 200 can utilize the information to automatically determine regions containing possible surface defects and report the possible defective regions to a user. For example, the system (e.g., through a user interface (UI) 218) could output a report, a graph, a map of the wafer, etc. In another example, a user can view the graph in FIG. 4A through a UI 218, locate standard deviation values that appear to stand out as compared to the majority of the standard deviation values, and pick out the corresponding image numbers to look at more closely to determine whether an actual defect exists.

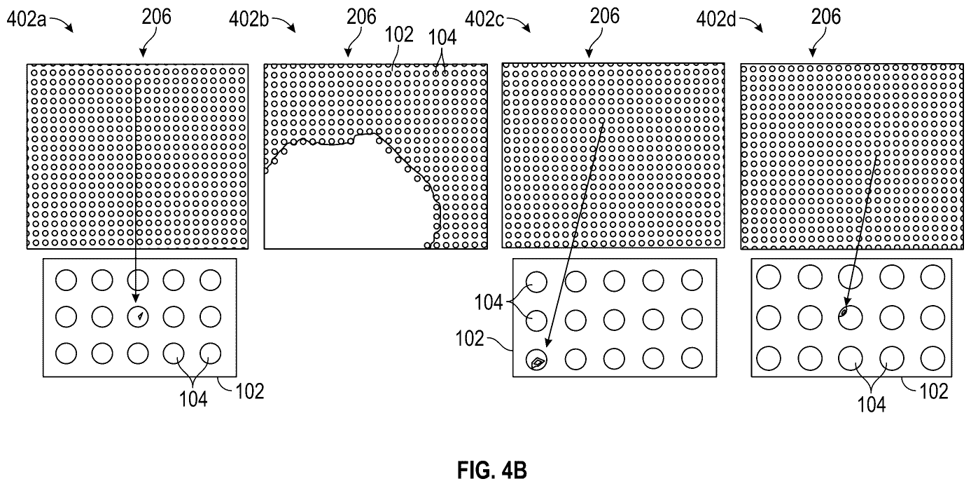

FIG. 5 is a schematic block diagram illustrating a method for inspecting a surface 212 of the semiconductor element 202, according to one embodiment. The optical profilometry apparatus 204 can be initialized prior to collecting data, as shown in step 502. In some embodiments, the initialization comprises running an autofocusing program or routine. In some embodiments, the initialization comprises running an auto tip-tilt program or routine. An autofocusing routine can help ensure that imaging of the surface 212 occurs at the same z-level across the semiconductor element 202 (e.g., for PSI imaging of a surface, adjustments are made such that portions of the surface are imaged at the same distance from the imaging lens, and thus the sample surface is in the same fringe of the greatest contrast).

Following initialization, an image 210 of the semiconductor element 202 is obtained (e.g., captured or acquired) in step 504. The image 210 of the semiconductor element 202 is processed in step 506 (e.g., processed by the processing electronics in the processing system 208). Processing can include reading in the image data and identifying and characterizing regions (e.g., regions of interest) in the image data, which can include distinguishing foreground from background through analyzing data by way of plotting line profiles or plotting histograms of surface heights. Other image analysis and image segmentation processes can be used, as will be appreciated by those of skill in the art.

Once the image data has been processed, the feature parameters can be identified and determined in step 508. For example, if an operator was interested in evaluating the quality of the metal pad surfaces 110, the operator can analyze the metal pad surfaces 110 based on the processed data and determine characteristics (e.g., a variability value) like recess (or protrusion), Rv, or Rt values. In step 510, the operator, through the processing electronics, computes statistical parameters corresponding to the desired features. As described herein, in one example, the values corresponding to the characteristics like recess (or protrusion), Rv, Rt, etc. can be plotted and/or statistical values (e.g., statistical parameter values such as standard deviations) can be determined, and the statistical values can then be further examined or evaluated or analyzed (e.g., plotted). Such statistical parameters can include standard deviation, mean, variance, etc. The statistical parameters are then compared against predicted values in step 512. For example, the operator can have prior knowledge of the surfaces to be analyzed and in one embodiment where a wafer comprises metal pads intended to all be approximately flat, abnormal or irregular standard deviations of the Rv values of such pads could be identified as those deviating substantially from zero. The operator can thus identify abnormal values and locate possible defects, as indicated in step 514. In some embodiments, a user interface 218 (e.g., graphical user interface) could be implemented and configured to indicate the location of defects or possible defects. In some embodiments, instead of (or in addition to) computing statistical parameters as shown in step 510, the parameters (e.g., recess values, Rv, and/or Rt) themselves can be individually collected and analyzed by the processing system 208 and compared with a threshold value to determine the existence of pads having abnormally high variability.

In one embodiment, the statistical parameters are linked to a PSI image number, which allows an operator to identify an abnormal statistical parameter (e.g., possible defect values 402a-d), determine the corresponding PSI image number, locate the PSI image based on the PSI image number, examine the PSI image, and determine whether a surface defect actually exists. If the operator determines a surface defect actually exists in a semiconductor element 202 (e.g., through visual inspection, etc.), the operator can discard the defective semiconductor element 202, cut out the defective portion of the element 202, or otherwise remove it from subsequent fabrication steps. For example, if the semiconductor element 202 had a surface prepared for hybrid bonding and it was found to contain damaged or irregular metal pads that would inhibit the formation of interconnects having sufficient electrical yield, the operator could remove this semiconductor element 202 from the fabrication process. The method allows for efficient and quick surface defect inspection, resulting in the identification of defective semiconductor elements that can be removed from the fabrication process, which in turn saves resources. In some embodiments, the inspection can occur on wafer surfaces prior to dicing. In some embodiments, the inspection can occur on singulated dies.

Although the above has been described for inspecting surfaces effectively including one foreground feature (e.g., metal pads 104) and a background (e.g., dielectric 102), the inspection technique and process can be used to evaluate surfaces having additional foreground features. Additionally, in some embodiments, the surface defect inspection can be used to evaluate surfaces comprising a single material. For example, the process could be used to determine the quality of a polishing step of a semiconductor element surface. In such embodiments, a semiconductor element can have an upper layer comprising the same material or multiple different materials at the outer surface. The processing system 208 can discretize the surface of the upper layer into multiple regions or portions, and the variability of a feature parameter can be determined for each region. For example, within a particular portion or region, the dielectric surface can have variable surface topology. The method described herein can be used to identify abnormally rough regions of the semiconductor element or regions where the depth of the dielectric layer is nonuniform.

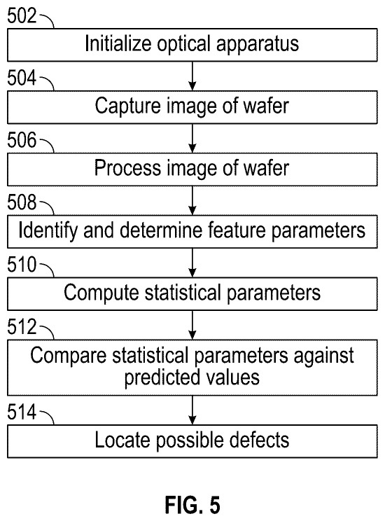

In some embodiments, a wafer-level map, as shown in FIG. 6, can be constructed from optical profilometric data and visualized through a user interface 218, enabling the formation of a big picture view of the quality of a semiconductor element surface 212. In one embodiment, a mean recess value (e.g., mean recess depth) of the metal pads 104 within a specified field of view (e.g., portion of a wafer or a die 206) can be obtained. Within a single field of view having some xy-position within a semiconductor element 202, the recess variation from the mean recess value can be determined and the information plotted as a map, providing a large scale understanding of a fabrication process (e.g., chemical mechanical polishing (CMP)) used to process the wafer surface. FIG. 6 illustrates wafer areas with Cu pads. In some embodiments, a wafer-level map based on optical profilometry (e.g., PSI) data can be constructed using tens of thousands of data points, covering millions of Cu pads (e.g., as illustrated in FIG. 6, a wafer-level based map can include 22,510 data points covering approximately 10 million Cu pads).

Such a procedure is beneficial because it can facilitate data collection beyond just sampling a handful of areas; it can relatively quickly provide information regarding an entire wafer surface (e.g., 200 mm wafer). For example, if the map of PSI data shows nonuniformity, this can indicate recess variation or possibly other dissimilar structures (e.g., oxidation, thickness, etc.). In some embodiments, this procedure allows an operator to evaluate a surface fabrication process as it applies to the entirety of the wafer. For example, in FIG. 6, radial properties are apparent with respect to the metal pads that have undergone chemical mechanical polishing (CMP), which is possibly indicative of the quality of the CMP process itself. Additionally, with this approach, it is possible to measure the recess variation in numerous samples in a high-volume production setting (e.g., lot-to-lot variation).

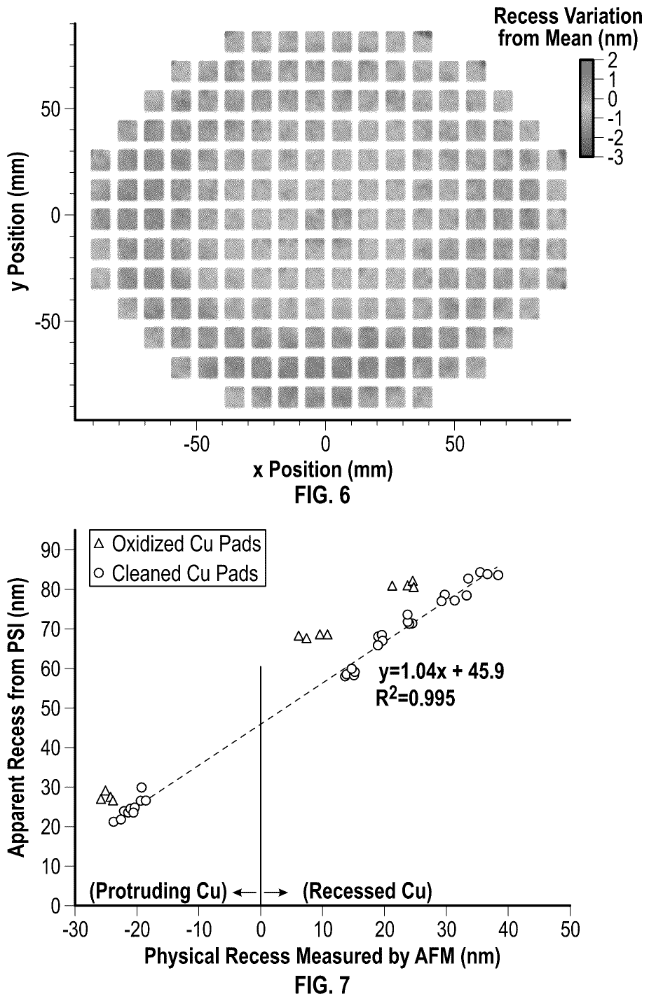

In some embodiments, an operator may be interested in the absolute values of various feature parameters themselves (e.g., recess depth values), as compared to operators using the statistical analysis procedures described herein, which may not rely on needing absolute values of feature parameters. In such cases, a calibration procedure can be implemented to take into account the sample dependency of optical profilometry techniques like phase shift interferometry (PSI). For example, because PSI imaging is sample dependent (e.g., depends on the index of refraction of the materials being imaged), imaging the surface 212 of a semiconductor element 202 comprising a dielectric 102 (e.g., SiO₂) and metal pads 104 (e.g., Cu) can yield values that are deeper than they physically are. In some embodiments, a calibration apparatus like an atomic force microscope (AFM) can be used to determine the actual or real recess values of the metal pads 104. The apparent values measured using PSI can then be plotted as a function of the actual values measured using AFM, as shown in FIG. 7. A relationship can be found between the two sets of data, which can allow an operator to determine how to calibrate the PSI data. For example, the plot in FIG. 7 demonstrates a linear relationship between the PSI and AFM data, with slope of 1 and a non-zero offset. From such a relationship, an operator would understand that to calibrate the apparent recess PSI data, the operator would need to subtract the offset value determined from the AFM data. In some embodiments, a user interface 218 can be configured to allow a user an option to run a calibration.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

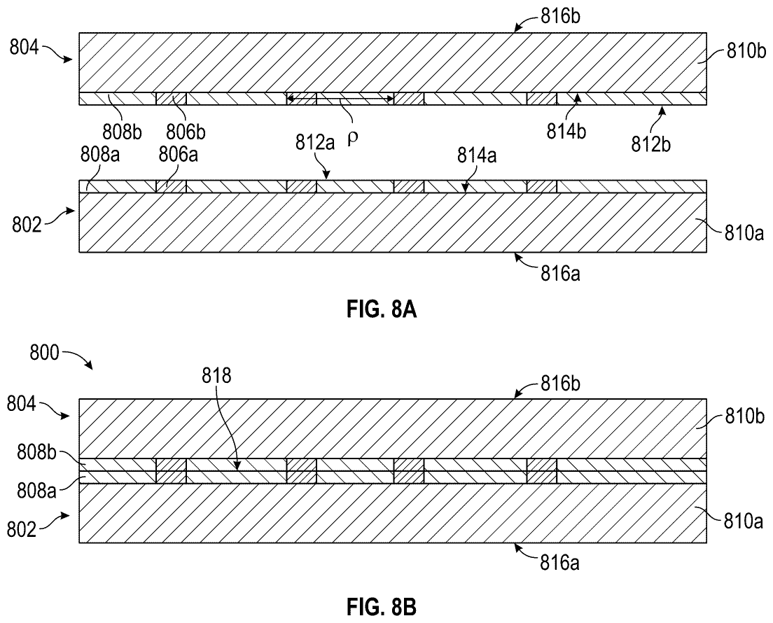

In various embodiments, the bonding layers 808a and/or 808b (see FIGS. 8A-8B) can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

In one aspect, the techniques described herein relate to a method for surface defect inspection, the method including: obtaining topographical data from one or more portions of a semiconductor element having a surface including a dielectric and a plurality of metal pads; processing the topographical data of the one or more portions of the semiconductor element to determine at least a first property of the plurality of metal pads; computing at least one variability value for the first property; and identifying candidate defects in the one or more portions of the semiconductor element based at least in part on the at least one variability value.

In some embodiments, the techniques described herein relate to a method, wherein the obtaining topographical data includes operating an optical profilometry apparatus having an automated sample stage and a processing system in electrical communication with the optical profilometry apparatus for capturing and processing the topographical data.

In some embodiments, the techniques described herein relate to a method, wherein obtaining topographical data includes capturing image data.

In some embodiments, the techniques described herein relate to a method, further including comparing the at least one variability value with a threshold value.

In some embodiments, the techniques described herein relate to a method, wherein the at least one variability value includes a statistical value.

In some embodiments, the techniques described herein relate to a method, wherein the statistical value includes a measure of variability.

In some embodiments, the techniques described herein relate to a method, wherein the measure of variability is a standard deviation.

In some embodiments, the techniques described herein relate to a method, wherein the at least one statistical value includes a measure of central tendency.

In some embodiments, the techniques described herein relate to a method, further including comparing the statistical value with a predicted statistical value.

In some embodiments, the techniques described herein relate to a method, wherein the first property includes at least one of a recess depth, Rv, or Rt.

In some embodiments, the techniques described herein relate to a method, wherein the topographical data includes phase shift interferometry data.

In some embodiments, the techniques described herein relate to a method, further including determining the one or more portions of the semiconductor element including the candidate defects and analyzing the one or more portions of the semiconductor element for one or more actual defects.

In some embodiments, the techniques described herein relate to a method, further including discarding the one or more portions of the semiconductor element including the one or more actual defects.

In another aspect, the techniques described herein relate to a method for surface defect inspection, the method including: acquiring a first topographical image of a semiconductor surface, wherein acquiring the first topographical image includes using an automated sample stage; processing the first topographical image, wherein the processing includes identifying a plurality of regions in the first topographical image; determining one or more feature parameter values for the plurality of regions in the first topographical image; and identifying a candidate defect indicator based on the one or more feature parameter values.

In some embodiments, the techniques described herein relate to a method, further including computing a statistical parameter value from the one or more feature parameter values.

In some embodiments, the techniques described herein relate to a method, further including identifying the statistical parameter value as the candidate defect indicator.

In some embodiments, the techniques described herein relate to a method, wherein the semiconductor surface includes a dielectric surface and one or more metal pads.

In some embodiments, the techniques described herein relate to a method, wherein the semiconductor surface includes a first material and a second material, and the first material is different from the second material.

In some embodiments, the techniques described herein relate to a method, wherein identifying the plurality of regions includes identifying regions including the first material and identifying regions comprising the second material.

In some embodiments, the techniques described herein relate to a method, wherein the first material includes a dielectric, and wherein the second material includes a metal.

In some embodiments, the techniques described herein relate to a method, wherein the metal includes copper.

In some embodiments, the techniques described herein relate to a method, further including reviewing the first topographical image after identifying the statistical parameter value as the candidate defect indicator and determining an existence of a surface defect of the semiconductor surface.

In some embodiments, the techniques described herein relate to a method, wherein the one or more feature parameter values include at least one of a recess depth, Rv, or Rt.

In some embodiments, the techniques described herein relate to a method, wherein the statistical parameter value includes at least one of a measure of central tendency or a measure of variability.

In some embodiments, the techniques described herein relate to a method, wherein the statistical parameter value includes a standard deviation.

In some embodiments, the techniques described herein relate to a method, wherein the first topographical image includes a phase shift interferometry image.

In some embodiments, the techniques described herein relate to a method, further including calibrating the one or more feature parameter values.

In some embodiments, the techniques described herein relate to a method, wherein the calibrating includes acquiring atomic force microscopy data of the first topographical image and comparing the atomic force microscopy data with the first topographical image.

In some embodiments, the techniques described herein relate to a method, further including computing a statistical parameter value from the one or more feature parameter values, wherein the one or more feature parameter values includes a recess depth, and wherein the statistical parameter value includes a mean recess depth.

In some embodiments, the techniques described herein relate to a method, further including determining a variation of the recess depth from the mean recess depth.

In some embodiments, the techniques described herein relate to a method, further including constructing a map of the variation of the recess depth from the mean recess depth of the semiconductor surface.

In some embodiments, the techniques described herein relate to a method, wherein the semiconductor surface includes at least a portion of a wafer.

In some embodiments, the techniques described herein relate to a method, wherein the semiconductor surface includes a portion of a wafer.

In some embodiments, the techniques described herein relate to a method, wherein the semiconductor surface includes a singulated die.

In another aspect, the techniques described herein relate to a method for surface defect inspection, the method including: acquiring a plurality of optical profilometry images of a wafer having a surface including a dielectric material and a conductive material; processing the plurality of optical profilometry images; computing one or more statistical parameters from the plurality of optical profilometry images, wherein the one or more statistical parameters includes a first statistical parameter; comparing the first statistical parameter against a predicted value of the first statistical parameter; and determining if the wafer includes a candidate defect after comparing the first statistical parameter against the predicted value of the first statistical parameter.

In some embodiments, the techniques described herein relate to a method, further including concluding the wafer includes the candidate defect.

In some embodiments, the techniques described herein relate to a method, further including identifying a first image of the plurality of optical profilometry images of the wafer including the candidate defect.

In some embodiments, the techniques described herein relate to a method, further including evaluating the first image for an actual defect.

In some embodiments, the techniques described herein relate to a method, wherein the plurality of optical profilometry images are phase shift interferometry images.

In some embodiments, the techniques described herein relate to a method, wherein the plurality of optical profilometry images include z-depth information.

In some embodiments, the techniques described herein relate to a method, wherein the first statistical parameter is a standard deviation.

In some embodiments, the techniques described herein relate to a method, wherein the surface further includes a plurality of recesses.

In some embodiments, the techniques described herein relate to a method, wherein the plurality of recesses includes copper.

In some embodiments, the techniques described herein relate to a method, wherein the surface includes a polished surface configured for hybrid bonding to a surface of a second wafer.

In another aspect, the techniques described herein relate to a surface defect inspection system, the system including: an imaging system configured to obtain image data for a wafer surface; and a processing system in electrical communication with the imaging system, wherein the processing system is configured to receive the image data acquired from the imaging system, and wherein the processing system includes processing electronics configured to: identify and characterize one or more regions in the image data; compute one or more statistical parameter values corresponding to the one or more regions; output the one or more statistical parameter values; and identify the one or more regions corresponding to the one or more statistical values including a possible defect value.

In some embodiments, the techniques described herein relate to a surface defect inspection system, wherein the imaging system further includes an automated sample stage, wherein the automated sample stage is configured to automatically move relative to an imaging path to facilitate acquisition of the image data.

In some embodiments, the techniques described herein relate to a surface defect inspection system, wherein the wafer surface is a prepared surface configured for hybrid bonding.

In some embodiments, the techniques described herein relate to a surface defect inspection system, wherein the imaging system includes a phase shift interferometry imaging mode.

In some embodiments, the techniques described herein relate to a surface defect inspection system, wherein the processing electronics are configured to extract features of the wafer surface corresponding to a plurality of copper pads.

In some embodiments, the techniques described herein relate to a surface defect inspection system, wherein the processing electronics are configured to compute a standard deviation of recess depth values of the plurality of copper pads.

In some embodiments, the techniques described herein relate to a surface defect inspection system, wherein the processing electronics are configured to compute a standard deviation of Rv values of the plurality of copper pads.

In some embodiments, the techniques described herein relate to a surface defect inspection system, further including an automated sample system, wherein the automated sample system is coupled to the imaging system, and wherein the automated sample system is configured to remove an imaged wafer from the automated sample stage and is configured to place an unimaged wafer on the automated sample stage.

In another aspect, the techniques described herein relate to a surface defect inspection system, the system including: a processing system configured to receive image data of a semiconductor element, wherein the processing system includes processing electronics configured to: identify and characterize one or more regions in the image data; compute one or more statistical parameter values corresponding to the one or more regions; output the one or more statistical parameter values; and identify the one or more regions corresponding to the one or more statistical values including a possible defect value; and a user interface configured to indicate which of the one or more regions are defective.

In some embodiments, the techniques described herein relate to a surface defect inspection system, wherein the processing system is in electrical communication with an optical profilometry apparatus, and wherein the optical profilometry apparatus is configured to acquire the image data.

In some embodiments, the techniques described herein relate to a surface defect inspection system, wherein the processing system is configured to calibrate the image data and the user interface is configured to allow a user an option to run a calibration.

In some embodiments, the techniques described herein relate to a surface defect inspection system, wherein the processing system is configured to determine a variation of a feature parameter value in the regions of interest from a mean feature parameter value, and wherein the user interface is configured to show a constructed map of the variation of the feature parameter value from the mean feature parameter value.

In some embodiments, the techniques described herein relate to a surface defect inspection system, wherein the semiconductor element is a prepared wafer surface configured for hybrid bonding.

In some embodiments, the techniques described herein relate to a surface defect inspection system, wherein the image data is phase shift interferometry image data.

In some embodiments, the techniques described herein relate to a surface defect inspection system, wherein the processing electronics are configured to extract features of the semiconductor element corresponding to a plurality of copper pads.

In some embodiments, the techniques described herein relate to a surface defect inspection system, wherein the processing electronics are configured to determine at least one of one or more portions of the semiconductor element including a possible defect value and analyze the at least one of the one or more portions of the semiconductor element for one or more actual defects.

In some embodiments, the techniques described herein relate to a surface defect inspection system, wherein the processing electronics are configured to discard the one or more portions of the semiconductor element including the one or more actual defects.

In another aspect, the techniques described herein relate to a surface defect inspection system, the system including: an imaging system to obtain image data for a wafer surface; and a processing system to receive the image data acquired from the imaging system, wherein the processing system is in electrical communication with the imaging system, and wherein the processing system includes processing electronics to: identify and characterize one or more regions in the image data; compute one or more statistical parameter values corresponding to the one or more regions; output the one or more statistical parameter values; and identify the one or more regions corresponding to the one or more statistical values including a possible defect value.

In some embodiments, the techniques described herein relate to a surface defect inspection system, wherein the imaging system further includes an automated sample stage, wherein the automated sample stage is configured to automatically move relative to an imaging path to facilitate acquisition of the image data.

In some embodiments, the techniques described herein relate to a surface defect inspection system, wherein the wafer surface is a prepared surface configured for hybrid bonding.

In some embodiments, the techniques described herein relate to a surface defect inspection system, wherein the imaging system includes a phase shift interferometry imaging mode.

In some embodiments, the techniques described herein relate to a surface defect inspection system, wherein the processing electronics are configured to extract features of the wafer surface corresponding to a plurality of copper pads.

In some embodiments, the techniques described herein relate to a surface defect inspection system, wherein the processing electronics are configured to compute a standard deviation of recess depth values of the plurality of copper pads.

In some embodiments, the techniques described herein relate to a surface defect inspection system, further including an automated sample system to remove an imaged wafer from the automated sample stage and to place an unimaged wafer on the automated sample stage, and wherein the automated sample system is coupled to the imaging system.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example+5%, +10%, +15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A method for surface defect inspection, the method comprising:
obtaining topographical data from one or more portions of a semiconductor element having a surface comprising a dielectric and a plurality of metal pads;
processing the topographical data of the one or more portions of the semiconductor element to determine at least a first property of the plurality of metal pads;
computing at least one variability value for the first property; and
identifying candidate defects in the one or more portions of the semiconductor element based at least in part on the at least one variability value.

2. The method of claim 1, wherein the obtaining topographical data comprises operating an optical profilometry apparatus having an automated sample stage and a processing system in electrical communication with the optical profilometry apparatus for capturing and processing the topographical data.

3. (canceled)

4. (canceled)

5. The method of claim 1, wherein the at least one variability value comprises a statistical value, wherein the statistical value comprises a measure of variability or a measure of central tendency.

6. (canceled)

7. (canceled)

8. (canceled)

9. The method of claim 5, further comprising comparing the statistical value with a predicted statistical value.

10. The method of claim 1, wherein the first property comprises at least one of a recess depth, Rv, or Rt.

11. The method of claim 1, wherein the topographical data comprises phase shift interferometry data.

12. The method of claim 1, further comprising determining the one or more portions of the semiconductor element comprising the candidate defects and analyzing the one or more portions of the semiconductor element for one or more actual defects.

13. (canceled)

14. A method for surface defect inspection, the method comprising:
acquiring a first topographical image of a semiconductor surface, wherein acquiring the first topographical image comprises using an automated sample stage;
processing the first topographical image, wherein the processing comprises identifying a plurality of regions in the first topographical image;
determining one or more feature parameter values for the plurality of regions in the first topographical image; and
identifying a candidate defect indicator based on the one or more feature parameter values.

15. The method of claim 14, further comprising computing a statistical parameter value from the one or more feature parameter values.

16. The method of claim 15, further comprising identifying the statistical parameter value as the candidate defect indicator.

17. (canceled)

18. The method of claim 14, wherein the semiconductor surface comprises a first material and a second material, and the first material is different from the second material.

19. (canceled)

20. The method of claim 18, wherein the first material comprises a dielectric, and wherein the second material comprises a metal.

21. (canceled)

22. The method of claim 16, further comprising reviewing the first topographical image after identifying the statistical parameter value as the candidate defect indicator and determining an existence of a surface defect of the semiconductor surface.

23. The method of claim 15, wherein the one or more feature parameter values comprise at least one of a recess depth, Rv, or Rt.

24. The method of claim 15, wherein the statistical parameter value comprises at least one of a measure of central tendency or a measure of variability.

25. (canceled)

26. The method of claim 14, wherein the first topographical image comprises a phase shift interferometry image.

27. (canceled)

28. (canceled)

29. (canceled)

30. (canceled)

31. (canceled)

32. (canceled)

33. (canceled)

34. (canceled)

35. A method for surface defect inspection, the method comprising:
acquiring a plurality of optical profilometry images of a wafer having a surface comprising a dielectric material and a conductive material;
processing the plurality of optical profilometry images;
computing one or more statistical parameters from the plurality of optical profilometry images, wherein the one or more statistical parameters comprises a first statistical parameter;
comparing the first statistical parameter against a predicted value of the first statistical parameter; and
determining if the wafer comprises a candidate defect after comparing the first statistical parameter against the predicted value of the first statistical parameter.

36. The method of claim 35, further comprising concluding the wafer comprises the candidate defect.

37. The method of claim 36, further comprising identifying a first image of the plurality of optical profilometry images of the wafer comprising the candidate defect and evaluating the first image for an actual defect.

38. (canceled)

39. (canceled)

40. (canceled)

41. (canceled)

42. The method of claim 35, wherein the surface further comprises a plurality of recesses, wherein the plurality of recesses comprises copper.

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)
